(19) United States
(12) Patent Application Publication
(10) Pub. No.: US 2010/0182019 A1
(43) Pub. Date: Jul. 22, 2010

(54) Method and apparatus for determining soil water content

(76) Inventor: William G. Gensler, Tucson, AZ (US)

Correspondence Address: William G. Gensler, 4020 E. Coronado Drive, Tucson, AZ, 85718, US

(21) Appl. No.: 12/321,218

(22) Filed: Jan. 20, 2009

(51) Int. Cl. G01R 27/26; E02D 17/00

(52) U.S. Cl. 324/664; 405/303

(57) ABSTRACT

This invention is concerned with a method and apparatus to measure soil water content. A sensor electrode assembly comprised of a sensor electrode fixed to a spherical shape is implanted in undisturbed soil at the bottom of a low narrow hole in the soil under evaluation. A second electrode is implanted in adjacent soil. Water is adsorbed on the surface of the sensor electrode in proportion to the water in the soil. Electrical charge layers are present at the sensor electrode/water interface due to dissolved oxygen in the adsorbed water. These charge layers result in an interfacial capacitance whose magnitude varies with the amount of water in the soil. Under the assumption that the capacitance of the second electrode/adjacent soil interface is constant, the change in capacitance across the two wires connected to the two electrodes give a measure of the change in soil water content. Energy flow during this measurement is unidirectional, that is, from the interfacial capacitance to the measuring device.

### REFERENCES CITED

U.S. Pat. No. 5,445,178 L. Feuer, 1995
U.S. Pat. No. 4,941,501 R. L. Bireley, 1990
U.S. Pat. No. 6,870,376 B1 W. G. Gensler Mar. 22, 2005
Wedlock, B. D. and J. K. Roberge (1969) Electronic Components and Measurements, Prentice Hal, Englewood Cliffs, N.J.
Hoare, J. P. (1968) The Electrochemistry of Oxygen. Wiley, NY.
Taiz, L. and Zeiger, E. (2009) Plant Physiology, 4th Ed. Sinauer Associates Inc. Publishers, Sunderland, Mass.
Bockris, J. O'M. and A. K. N. Reddy. (1970) Modern Electrochemistry Volume 2 Plenum Publishing, NY.

### FIELD OF THE INVENTION

This invention generally relates to agricultural and forestry measurements and more particularly to a method and apparatus for measurement of soil water content.

### DEFINITION

The word “medium” as used herein is defined as the combination of the soil and the water in the volume under evaluation.

### PRIOR ART I

### Soil Water Content Measurement Based on Properties of the Medium

Soil water content measurements have been made in a variety of ways. A simple method is to place a block of porous material into the medium, partially evacuate the air in the material and then determine the rate of penetration of water into the block by a measurement of a change in air pressure within the block. The disadvantage of this method is the different rates of water movement into the block in different types of medium. A further disadvantage is the change in medium structure as the medium dries out; for example, cracking in the soil. This leads to a non uniform movement into the porous block.

An equally simple method is to place a porous block in the medium and measure the electrical resistance between two points in the block. As water moves into the block, the resistance between the two points in the block changes and gives a measure of the amount of water in the pathway between the two points. The disadvantage of these two methods is that both are sensitive to the amount of chemical constituents such as salt in the medium. This influences the reading. The salt remains within the block to influence subsequent readings.

Another more complex method is to insert a long tube permanently into the medium. A source of neutrons is then lowered into the tube and the neutrons permitted to move out into the medium. The absorption of the neutron stream by water in the medium gives a measure of how much water is present in the region contiguous to the tube. Energy flow in this method is from the measuring device into the medium.

A method similar to this utilizes the same tube but electronics is lowered into the tube. Radio frequency energy is then emitted from the electronics. Some of this energy is absorbed by water in the medium. The amount of energy that is absorbed is measured by another section of the electronics. Energy flow in this device is from the measuring device into the medium as well.

These last two mentioned methods have the advantage that the measurement apparatus can be lowered to different depths such that medium water content can be measured at each depth sequentially. A further advantage is the assessment of soil water content in a volume near the outside surface of the tube, but not contiguous to it.

A disadvantage of all these methods is the size of the block or tube. The physical dimension of the sensor is in the order of 10 centimeters. This size requires digging and extensive disturbance of the medium structure. Furthermore, the pathway for water movement is significantly disturbed. This impedes the lateral flow of water. The tube itself provides a vertical pathway for water percolation along its sides. A further disadvantage of the neutron method and apparatus is the requirement of a licensed operator to make the measurement. These aspects of placement of the sensor lead to significant equilibration time before the soil has re-stabilized and the measured values stabilize. This may take months and even years.

### PRIOR ART II

### Soil Water Content Measurement Using Change in Dielectric Constant of the Medium to Indicate Changes in Soil Water Content

U.S. Pat. No. 5,445,178 (Feuer, 1995) employs an electronic circuit and a pair of “conductive sensor elements” implanted in the medium (Feuer, Abstract and claim 1, U.S. Pat. No. 5,445,178). The circuit consists of an electronic oscillator, the pair of conductive sensor elements located in the medium whose water content is to be ascertained and the volume between the conductive elements. The sensing elements are contiguous. Energy flow is from the oscillator into the sensing elements. The principle of operation is variation of the dielectric constant of the medium with the water content of the medium.

U.S. Pat. No. 4,941,501 (Bireley, 1990) employs similar circuitry. The apparatus is similar to the Feuer Patent insofar as energy flow is from the electronics to the sensing elements. Both sensing element are located in the medium whose water content is to be measured. The principle of operation is similar to the Feuer Patent.

The fundamental characteristics of the Feuer and Birely Patents and their relation to this invention can best be evaluated by beginning with the definition of capacitance. Capacitance (linear or non linear) is the ratio of the change in charged stored in two opposing charge layers to the change in potential across the charge layers (Wedlock and Roberge, Eqn. 8.1). These changes are evaluated at a particular potential. The linear form of this definition is simply the ratio of stored charge of one of the two opposing layers of charge to the potential across the two layers of charge. The charge layers and medium between the charge layers form the capacitor whose capacitance is being measured. In electrical circuits capacitance is measured between two wires connected to the terminals of the measuring device. In terms of a simple idealized physical apparatus, the capacitor consists of two parallel plates of equal area separated by a medium. The plates contain equal and opposite charges. The capacitance value (in farads) of this array is given by (Wedlock and Roberge, Eqn. 8.2)

Capacitance=(Area of the plate*dielectric constant*vacuum permittivity)/Distance between the plates (1)

The dielectric constant, K, is defined by the relation

dielectric constant,K=permittivity of the medium/permittivity of a vacuum (2)

The permittivity of a vacuum is given by 8.85*10e−11 farads/meter

To apply this definition to an evaluation of the above named Patents and to gain insight into how the above named Patents and this invention differ, it is necessary to first determine the location of the two charge layers in the above named Patents. This requires a determination of the circuit path in the above named Patents. The circuit path begins with one wire connected to the external measuring device and proceeds along the wire to the conductive sensing element. The first charge layer exists at the surface of this sensor element. The charge itself is composed of electrons. The circuit path continues into and through the medium which is being measured to the second conductive sensor element. The second charge layer is located on the surface of the second element. The charge itself is composed of electrons (actually a deficit of electrons) as well. The circuit path then continues back to the second wire of the measuring device. The capacitor consists of these two charge layers separated by the medium. The variation in capacitance depends on a variation in the dielectric constant of the medium (claim 1, U.S. Pat. No. 5,445,178). The charge layers arise because of an external potential impressed across the two sensing elements. The medium is a major part of the capacitor being measured in the above named Patents. It is a major part of the apparatus in the above named Patents. The sensing elements are termed “conductive.” The conductive sensor elements are flat, coplanar plates (claim 12, U.S. Pat. No. 5,445,178).

The similarity and differences between the apparatus and method in the above named Patents and the apparatus and method in this invention will be discussed in the Objects and Advantages section below after the method and apparatus in this invention are presented.

### PRIOR ART III

### Soil Water Content Measurement Using Change in Interfacial Capacitance of a Sensing Electrode Implanted in the Medium to Indicate Changes in Soil Water Content

U.S. Pat. No. 6,870,376 (Gensler, 2005) claims an apparatus and method wherein a sensing electrode is resident within a plant. A second electrode is resident in the root zone. The root zone resides in the medium. Capacitance changes at the interface of the sensing electrode and the water adsorbed on the surface of the sensing electrode is measured. The circuit path of the apparatus in U.S. Pat. No. 6,870,376 begins at a terminal of the measuring device and proceeds along a wire connected to the sensing electrode resident in the plant. The circuit path crosses the sensing electrode/tissue interface, through the extracellular region of the plant to the roots of the plant. The path then crosses out of the roots into the medium. The circuit path continues through the medium to a second electrode located in the medium or an adjacent region conductively connected to the medium. The circuit path crosses the medium/second electrode interface and proceeds along the wire connected to the second electrode back to the other terminal of the measuring device. The similarity and differences between the apparatus and method in U.S. Pat. No. 6,870,376 and the apparatus and method in this invention will be discussed in the Objects and Advantages section below after the method and apparatus in this invention are presented.

### OBJECTS AND ADVANTAGES

### Major Parts of the Apparatus

The apparatus in this invention has four major parts:
1. Sensor Electrode Assembly, Label 2 and 6 in FIG. 1
2. Medium, Label 3 in FIG. 1
3. Adjacent Region, Label 11 in FIG. 1
4. Second Electrode, Label 5 in FIG. 1
   Each of these parts will now be discussed.

### 1. Sensor Electrode Assembly

The sensor electrode assembly is comprised of a sensor electrode and a spherical shape fixed to the end of the sensor electrode. A wire connects the sensor electrode to a measuring device located above the surface of the medium.

The salient characteristic of the sensing electrode is the water adsorbed on the sensor surface. Not all the sensor surface is covered with water, that is, wetted with water. The principle of operation of this invention is that the area of the sensor surface that is wetted is proportional to the amount of water in the medium. As the water content of the medium increases the wetted surface area increases and vice versa. The sensor electrode functions as a water dipstick closely analogous to an oil dipstick in an automobile.

Within this water there is a layer of electrical charge. This layer of charge is composed primarily of ionized oxygen (Hoare, 1964). This layer of charge and an induced layer of electrons at the surface of the metal form two plates of an electrical capacitor such as described in Eqn. 1. These two layers of charge arise because of the intrinsic characteristic of a metal/liquid interface. The magnitude of the two layers is enhanced because the metal is noble, that is, made of material which does not permit facile transfer of electrons from metal to ions within the adsorbed liquid layer, but at the same time has a large magnitude of ionized oxygen within the adsorbed layer. The presence of the two layers of electrical charge is intrinsic in the interface. It is not present because of any external device capable of producing an electrical potential across the interface. An electrical potential exists across the interface because of the intrinsic presence of these two layers of charge. The distance between these charge layers is approximately 10 nanometers (Bockris and Reddy, 1970).

A spherical shape is fixed to end of the sensor electrode. The spherical shape has no capacitive characteristics, in other words, it is electrically non reactive.

The spherical shape is a necessary part of the electrode assembly for three reasons. The first reason concerns placement of the sensing electrode into the deep narrow hole in the medium. One cannot simply lower the electrode into the hole because it catches on the side of the hole and cannot move further downward. The electrode must be guided down to the bottom of the hole. This guidance is provided by attaching the spherical shape at the end of the electrode assembly to the end of a rigid tube and lowering the tube down to the bottom of the hole.

The second reason a spherical shape is necessary is to force the filament into undisturbed medium. The filament itself has no mechanical rigidity. The spherical shape is pressed into the undisturbed medium and the filament comes along as part of the assembly. It is not malformed in the act of placement but retains its linear form.

The third reason the spherical shape is part of the electrode assembly is to permit release of the filament following placement. The spherical shape holds the filament in the undisturbed medium while the placement tube is extracted.
A narrow hole is required in soil water content sensing because soil structure, once disturbed, is very slow to return to the undisturbed condition. One is speaking in terms of months or years to recover. This renders the measurement of soil water content suspect in a manner that is difficult to verify because water percolation from the surface is difficult to measure without more disturbance. Disturbance to the medium is a major aspect of valid soil water content measurements.

### 2. Medium

The medium is comprised of soil and water. In this invention the major characteristic of the medium, outside of its water content, is its ability to conduct ionic current. The dielectric constant of the medium is of no importance in this invention. It has no influence on the principle of operation. Since soil and water both are strongly ionic in nature, the ionic conductivity of the medium is excellent.

The disturbance to the medium is a hole approximately 12 millimeters in diameter and as deep as 180 centimeters. The depth dimension is set by the longest drill bit commercially available even by special order. Deeper more narrow holes are simply too dangerous to drill because of the possibility of bit shatter. The sensor electrode diameter is in the order of tenths of millimeters. The only reason for the large diameter hole is the non-availability of long narrow drill bits, even by special order.

The depth of the sensing electrode in the medium is set by the depth of the functional root mass in the medium.

### 3. Adjacent Region

The adjacent region is simply a region conductively connected to the medium either laterally or vertically. For example, the medium may be the volume below the drip line in an agricultural field. The adjacent region is a volume not directly under the drip line. The distinction is drawn because the second electrode is preferably located in a region that is not subjected to large scale changes in water content.

### 4. Second Electrode

The second electrode resides in the adjacent region. The second electrode has physical and functional characteristics different from the sensing electrode. It is made of different material from the material of the sensing electrode. The material of the second electrode is selected to permit facile transfer of electrical current across the interface between the material of the second electrode and the adjacent region. Electrical current is carried by electrons in the metal of the second electrode. Electrical current is carried by ions present in the liquid in the adjacent region. The wetted surface area of this electrode is very large. This results in a lower electrical potential difference across the interface for the same magnitude of electrical charge transfer across the interface. In other words, second electrode/adjacent region interface acts more like a small electrical resistor and less like an electrical capacitor.

The distance between the sensing electrode assembly and the second electrode can be as great as one hundred meters.

Circuit Path in this Invention

The circuit path in this invention consists of connecting the four parts of the apparatus described above. Wires connect the two electrodes to a measuring device located above the surface. The measuring device determines the capacitance between the two wires connected to its terminals.

Differences Between this Invention and U.S. Pat. Nos. 5,445,178 and 4,941,501

The differences between the above named Patents and this invention have their origin in the fact that the capacitor whose capacitance is being measured is different in the above named Patents from the capacitor whose capacitance is being measured in this invention.

These differences are manifest in six fundamental characteristics.

1) In the above named Patents, electrical energy flow is from the external measuring device to the medium. In this invention, electrical energy flow is from the medium to the external measuring device. This is exactly opposite to the apparatus in the above named Patents.

2) In the above named Patents, two similar sensing elements are employed both of which are located in the medium whose water content is to be measured. The circuit path is exclusively through the medium. In this invention only one sensing electrode is located in the medium to be measured. A second electrode is located outside of the medium in an adjacent region.

3) In the above named Patents, the two sensing elements have a similar function. In this invention, a second electrode is employed whose only function is to return electrical charge to the external measuring device.

4) In the above named Patents, the principle of operation is based on a variation of the dielectric constant of the medium as a whole as the water content of the medium varies. In this invention, the principle of operation is based on an amount of water adsorbed at the sensing electrode surface. The dielectric constant of this water is constant. The principle of operation is based on a variation of the area of the water adsorbed on the surface of the sensing electrode.

5) In the above named Patents, the charge on the two opposing charge layers are electrons or a deficit of electrons. In this invention the charge on one of the two opposing charge layers is electrons. The charge on the other opposing layer is ions.

6) In the above named Patents, the sensing electrodes exist in pairs. In this invention many sensing electrode assemblies can be used with a single second electrode through the use of a multiplexer. The latter device simply connects in sequence a large number of sensor electrodes to the measuring device.

The difference between the above named Patents and this invention can also be seen by examination of the physical description of the parallel plate capacitor. The above named Patents are based on changes in the value of capacitance that arise from changes in the value of the dielectric constant in Eqn. 1 at constant area of the plates and distance between the plates. In this invention changes in capacitance arise from changes in the area of the plates at a constant value of dielectric constant and distance between the plates.

In the above named Patents, the physical distance between the two charged plates is in the order of one centimeter. In this invention the physical distance between the two charged plates is in the order of ten nanometers. The difference between these two distances is six orders of magnitude. This clearly indicates that different mechanisms are operative in the above named Patents and this invention.

Differences Between this Invention and U.S. Pat. No. 6,870,376

The differences between the Apparatus and Method taught in U.S. Pat. No. 6,870,376 and this invention have their origin in the primordial difference between soil and living tissue. Living tissue is not soil. U.S. Pat No. 6,870,376 concerns living tissue. This invention concerns soil.

These differences are manifest in four fundamental characteristics:

1) Plant tissue is aerobic because of the presence of lenticels and stomates (Taiz and Zeiger, 2006). Both of these tissue elements serve to permit facile transfer of gases such as oxygen and carbon dioxide into and out of the plant. This insures a dissolved oxygen level in the water in the extracellular region that is in equilibrium with oxygen levels outside of the plant. This is not necessarily the case with the medium. Aerobic conditions may or may not exist in the medium. Lack of oxygen in the soil is the major problem that arises from overwatering agricultural fields. ‘The dissolved oxygen level in the water in the medium may or may not contain dissolved oxygen levels in equilibrium with the atmosphere. This means that the capacitor composed of a layer of ionized oxygen within the water adsorbed on the surface of the sensing electrode may be variable in magnitude due to a variation in dissolved oxygen concentration. If it exists it may not be constant in magnitude such that the variation in amount of wetted surface area alone determines the value of capacitance across the interface. This is a major difference in a soil water content sensor and a plant water content sensor using interfacial capacitance variations as an operating principle.

2) A second difference lies in the source of water variations in this invention and in U.S. Pat. No. 6,870,376. The medium in the apparatus of U.S. Pat No. 6,870,376 is not a combination of soil and water. It is a ring of living cells surrounding the perimeter of the sensor electrode. Cells extrude water into the extracellular region during the normal diurnal cycle which in turn causes a diurnal cycle in the measured capacitance. In other words, the variation in capacitance arises from an active physiological process. Water is brought to or taken away from the surface of the electrode as a result of this process. The medium in a soil water content measurement has no active energy source causing water content differences at the surface of the sensor. Variation in capacitance arises from water movement due to purely inorganic energy gradients such as capillarity or convection. Consider an analogy to the medical field. Measurement of pressure variations in the human heart is done with an instrument that is basically different than the instrument for measurement of pressure differences that occur in a utility water line.

3) A third difference of this invention and the invention claimed in U.S. Pat. No. 6,870,376 arise from the energy gradients that provoke water movement in the vicinity of the sensing electrode. The energy gradients vary with the type of soil. For example, clay, particle diameter is less than two micrometers. Coarse sand, particle has a particle diameter of 1000 micrometers. This leads to entirely different water movement characteristics (Taiz and Zeiger, Table 4.1). This wide variation is not present in plant tissue wherein cell size is relatively uniform independent of the genus and species. This leads to specific differences in the physical design of the sensing electrode and the method of placement of the electrode in the medium.

4) A fourth difference of this invention and U.S. Pat No. 6,870,376 is the sensing electrode. The sensing electrode in U.S. Pat No. 6,870,376 consists of only a filament. The sensing electrode in this invention is part of an assembly comprised of a thicker and longer filament and a spherical shape attached to the end of the electrode. As was pointed out above, the spherical shape at the end of the electrode is an essential part of the electrode assembly. One cannot implant the sensor in undisturbed medium without this shape attached to the sensor electrode.

### FIGURES

FIG. 1 is an illustration of the sensor electrode assembly in undisturbed medium below the bottom of the hole in the medium and the second electrode in the adjacent region. The first wire and second wire emerge on the surface (This figure is not drawn to scale).

FIG. 2 is an example of the diurnal cycle of the medium water content in walnuts in Turlock, Calif.

### REFERENCE NUMERALS IN FIGURE

1 First wire connected to the sensor electrode
2 Sensor electrode
3 Medium
4 Second wire connected to the second electrode
5 Second electrode
6 Spherical shape
7 Surface of the medium
8 Hole in the medium
9 Undisturbed medium
10 Measuring device
11 Adjacent region

### DESCRIPTION

### Apparatus

This invention is comprised of an apparatus and method to measure water content in medium 3 composed of soil and water. When a noble metal sensor electrode 2 is implanted in medium 3, water within medium 3 adsorbs on the surface of sensor electrode 2. Oxygen within this water ionizes and forms a charge layer in close proximity to the metal surface. A layer of electrons forms on the surface of the metal opposite to the oxygen charge layer in the liquid. These two charge layers form an electrical capacitor whose magnitude is proportional to the wetted surface area of the sensor electrode surface. The sensor electrode assembly consists of sensor electrode 2 and spherical shape 6.

First wire 1 is connected from measuring device 10 to sensor electrode 2. Sensor electrode 2 is buried in medium 3 whereupon part of the sensor electrode 2 surface is wetted by water in medium 3. The result is a capacitor across the sensor electrode surface and adsorbed water on the surface. In order to measure variations in this capacitance, second electrode 5 is buried in adjacent region 11 conductively connected to medium 3. Second electrode 5 is connected to second wire 4. Second wire 4 is connected to measuring device 10.

The electrochemical circuit path begins at measuring device 10, proceeds along first wire 1 to sensor electrode 2. The circuit path moves across the sensor electrode 2/medium 3 interface. The circuit path continues through medium 3 and adjacent region 11 to second electrode 5. Medium 3 and adjacent region 11 are conductively connected. The circuit path moves across the adjacent region 11/second electrode 5 interface to second wire 4. Second wire 4 is connected to the other terminal of measuring device 10.

### Method

The capacitance across the ends of first wire 1 and second wire 4 is determined by measuring device 10. As the water content of medium 3 changes, the wetted surface area of sensor electrode 2 changes. If the capacitance of the second electrode 5/adjacent region 11 interface is constant, any change in the capacitance measured across first wire 1 and second wire 4 can be attributed to a change in the capacitance of the sensor electrode 2/medium 3 interface. The capacitance of the sensor electrode 2/medium 3 interface is proportional to the magnitude of the wetted surface area of sensor electrode 2. As the wetted surface area increases and decreases, the interfacial capacitance increases and decreases, respectively. The measured capacitance is proportional to changes in the wetted surface area of the sensor electrode 2/medium 3 interface. Changes in the measured capacitance then indicates changes in the water content of medium 3.

Part of the surface area of sensor electrode 2 is covered with water and part of the surface is covered with air. Changes in the measured capacitance can be larger or smaller depending on the magnitude of the total surface area of sensor electrode 2 in medium 3. In order to obtain to base the measured capacitance on a fixed, standard value, a second measurement is required. This second measurement is the total surface area of sensor electrode 2 buried in medium 3. The measured capacitance is divided by this total surface area to form a ratio of measured capacitance to total surface area. The changes in this ratio become a measure of changes in medium 3 water content. The reported output has the units of farads/meter squared. The maximum value of this ratio occurs when the entire surface of sensor electrode 2 is wetted.

### CONCLUSIONS, RAMIFICATIONS AND SCOPE OF INVENTION

The water content of soil can be determined by placing a sensor electrode in the medium and a second electrode in an adjacent region to form an electrochemical circuit. Water in the medium causes a wetting of the sensor electrode surface thereby generating an electrical capacitance across the medium/sensor electrode interface. Electrical capacitance is measured across a wire connected to the sensor electrode and a wire connected to the second electrode. If the capacitance of the second electrode/soil interface is constant, changes in the capacitance measured across the two wires becomes a measure of changes in electrical capacitance across the sensor electrode/medium interface, and in turn, a measure of changes in the water content of the medium. As the soil water content increases, the measured electrical capacitance increases and vice versa. The sensor electrode functions as a water dipstick analogous to an oil dipstick in an automobile engine.

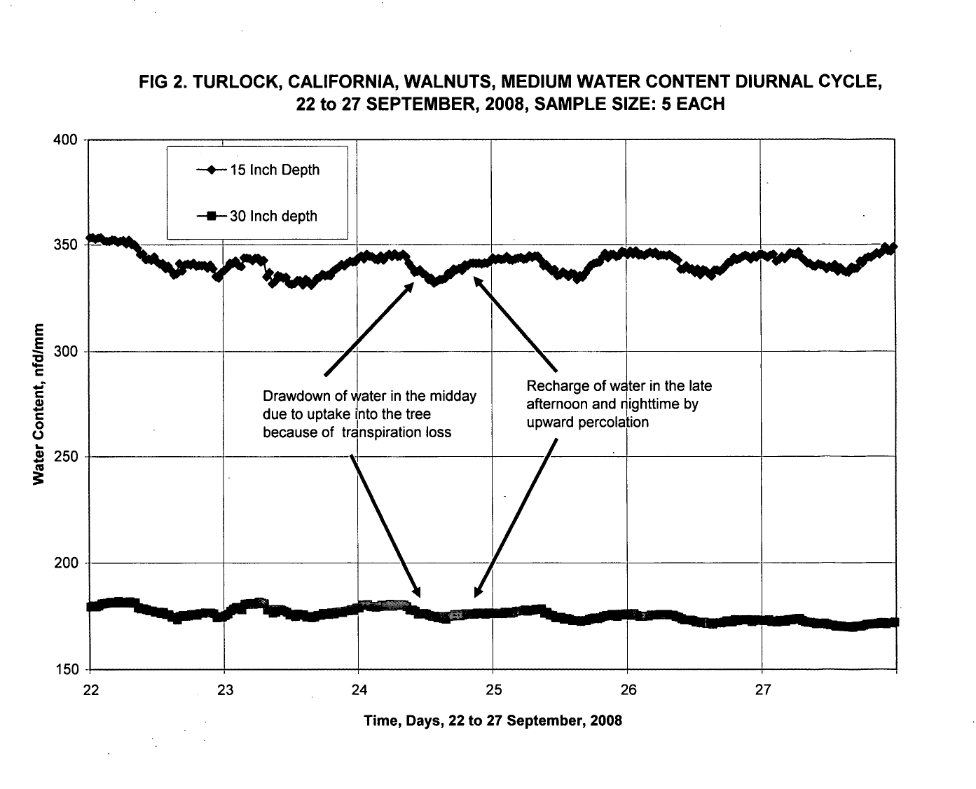

FIG. 2 gives an example of the change in measured capacitance as a measure of change in soil water content. The water content diurnal cycle of the medium is phase delayed compared to the diurnal cycle in the water content of the tree. The tree water content cycle is closely correlated with the sun cycle. The tree transfers water into the atmosphere using water contained in its canopy during the period from dawn to 1000 hours. At about 1000 hours it begins to draw water from the medium.

The sensor electrode can be implanted in undisturbed soil by first drilling a hole in the medium. A spherical shape is then permanently attached to the end of the sensor electrode. This assembly is first inserted in the bottom of the hole and then forced downward into undisturbed medium at the bottom of the hole. This results in virtually normal lateral movement of water in the vicinity of the sensor electrode surface.

Near undisturbed vertical movement of water in the vicinity of the sensor electrode assembly is enhanced by refilling the drilled hole with native soil at each depth level. This refill is accomplished by eroding the sides of the drilled hole with high pressure water thereby encasing the wire from the sensor electrode and ensuring vertical movement of water close to the pre-placement level. Abnormal vertical percolation is minimized.

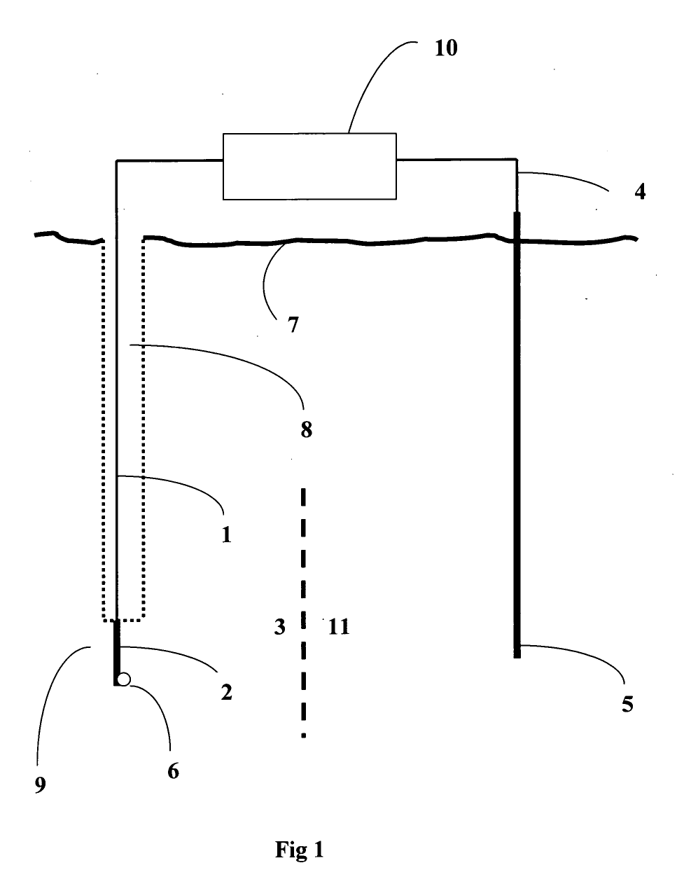

Although FIG. 1 illustrates vertical orientation of the sensor electrode, any orientation is feasible. For example, an off-vertical drill hole will further decrease abnormal downward percolation of water in the vicinity of the sensor electrode assembly.

A spherical shape permits easy release of the sensor electrode after placement in undisturbed soil. This is the preferred embodiment, although other shapes are feasible.

A cylindrical sensor electrode shape is the preferred embodiment. This shape will permit the most facile water movement across and around the sensor electrode surface and insure uniform wetness on the surface.

An embodiment similar in function to a cylindrical electrode and an electrochemically inert spherical shape fixed to the end of the electrode would be solely an electrochemically active spherical electrode. There would be no filament. The surface of the sphere functions in similar manner to the surface of the cylinder of the filament.

The second electrode also has many embodiments. Its size and shape and material will vary. In order to maintain a large difference between the interfacial capacitance of the two electrodes, it is best to use a sensor electrode material that has a high level of water adsorption and ionization and a low level of equilibrium electron transfer across the interface. By contrast, the second electrode should have a high level of water adsorption, minimum oxygen ionization and a high level of equilibrium electron transfer across the interface. This is not essential, but will yield maximum resolution and range. It is best to use a second electrode that has a large surface area compared to the surface area of the sensor electrode. This will minimize any interfacial resistance.

While there have been illustrated and described various embodiments of the present invention, it will be apparent to those skilled in the art that modification thereof will occur to those skilled in the art. It is intended in the appended claims to cover all such changes and modifications that fall within the true scope and spirit of the present invention.

I claim:

1. A method of measuring the water content within a medium comprising the steps of:
measuring the surface area of a sensor electrode,
fixing a shape to the end of said sensor electrode to form a sensor electrode assembly,
placing said sensor electrode assembly in any gravitational orientation in said medium,
placing a second electrode in an adjacent region conductively connected to said medium,
measuring the electrical capacitance between a first wire connected to said sensor electrode of said electrode assembly and a second wire connected to said second electrode using a measuring device in which electrical energy flow is only from said sensor electrode to said measuring device,
forming a ratio of said electrical capacitance to said surface area of said sensor electrode of said sensor electrode assembly.

2. Apparatus for measuring the water content within a medium comprising:
a sensor electrode assembly comprised of a sensor electrode and shape for making contact with said medium,
a second electrode for making contact with an adjacent region conductively connected to said medium,
a first wire connected to said sensor electrode assembly, a second wire connected to said second electrode,
means coupled to said first wire and said second wire for measuring the electrical capacitance generated at the interface between said sensor electrode and adsorbed water on the surface of said sensor electrode wherein the energy flow during the measurement is only from said interface to said measuring means,
means for measuring area of said sensor electrode of said sensor electrode assembly implanted within said medium.

3. Apparatus as recited in claim 2 further including a plurality of sensor electrode and a selective connector interposed between each of said sensor electrodes and said measuring means for selectively connecting each one of the said sensor electrodes to said measuring means.

4. Apparatus as recited in claim 2 wherein the sensor electrode has a surface that is electrochemically active and further has a shape that facilitates implant.
